(19) United States
(12) Patent Application Publication
(10) Pub. No.: US 2020/0203146 A1
(43) Pub. Date: Jun. 25, 2020

(54) MODULE AND SYSTEM FOR TRIMMING WAFER EDGE

(71) Applicant: XIA TAI XIN SEMICONDUCTOR (QING DAO) LTD., Qingdao (CN)

(72) Inventor: SUN-WUNG LEE, Singapore (SG)

(21) Appl. No.: 16/671,695

(22) Filed: Nov. 1, 2019

Related U.S. Application Data
(60) Provisional application No. 62/781,024, filed on Dec. 18, 2018.

(51) Int. Cl. H01L 21/02; H01L 21/306; B24B 37/20; H01L 21/67; B24B 37/005

(52) U.S. Cl. CPC H01L 21/02021; H01L 21/30625; B24B 37/005; H01L 21/6715; H01L 21/02013; B24B 37/20

(57) ABSTRACT

A wafer trimming module is provided. The wafer trimming module includes a holder and a polishing pad. The holder has an opening. The polishing pad is attached to a bottom and a sidewall of the opening. The polishing pad is compressible.

### CROSS REFERENCE TO RELATED APPLICATIONS

The present application claims the benefit of and priority to U.S. Provisional Application No. 62/781,024, filed on Dec. 18, 2018, the contents of which are incorporated herein by reference.

### FIELD

The present disclosure relates to semiconductor fabrication and more specifically to a semiconductor wafer edge trimming apparatus.

### BACKGROUND

Particles generated from the semiconductor fabricating process tend to accumulate on wafer edge and cause defects thereon. Certain methods may be performed to remove residual particles on the wafer edge. However, existing methods require large space in the chamber for installation of a cleaning device.

### SUMMARY

The following presents a summary of examples of the present disclosure in order to provide a basic understanding of at least some of its examples. This summary is not an extensive overview of the present disclosure. It is not intended to identify key or critical elements of the present disclosure or to delineate the scope of the present disclosure. The following summary merely presents some concepts of the present disclosure in a general form as a prelude to the more detailed description provided below.

In one embodiment, a wafer trimming module includes a holder and a polishing pad. The holder has an opening. The polishing pad is attached to a bottom and a sidewall of the opening. The polishing pad is compressible.

In another embodiment, a wafer trimming module includes a holder, a liquid supply member, and a polishing pad. The holder has an opening. The liquid supply member is attached to a bottom and a sidewall of the opening. The polishing pad is coupled to the liquid supply member. The polishing pad is compressible.

In yet another embodiment, a wafer trimming system includes a control unit and at least one wafer trimming module. The at least one wafer trimming module is configured to attached to the control unit. The at least one wafer trimming module includes a holder, a liquid supply member, and a compressible polishing pad. The holder has an opening. The liquid supply member is attached to a bottom and a sidewall of the opening. The compressible polishing pad is attached to the liquid supply member and the sidewall of the opening.

The details of one or more examples are set forth in the accompanying drawings and description below.

### BRIEF DESCRIPTION OF THE DRAWINGS

The accompanying drawings illustrate one or more implementations of the present disclosure and, together with the written description, explain the principles of the present disclosure. Wherever possible, the same reference numbers are used throughout the drawings referring to the same or like elements of an embodiment.

FIG. 1 is a schematic diagram of a chemical-mechanical planarization (CMP) apparatus.

FIG. 2A is a cross-sectional view of a wafer trimming module in accordance with an implementation of the present disclosure.

FIG. 2B is a cross-sectional view showing dimensions of the wafer trimming holder in accordance with an implementation of the present disclosure.

FIGS. 3A and 3B are side views of a chamber having a vertical wafer trimming system in accordance with an implementation of the present disclosure.

FIG. 4 is a side view of a chamber having a horizontal wafer trimming system in accordance with an implementation of the present disclosure.

FIG. 5 is a cross-sectional view of a wafer trimming module in accordance with an implementation of the present disclosure.

### DETAILED DESCRIPTION

To facilitate an understanding of the principles and features of the various implementations of the present disclosure, various illustrative implementations are explained below. Although exemplary implementations of the present disclosure are explained in detail, it is to be understood that other implementations are contemplated. Accordingly, it is not intended that the present disclosure is limited in its scope to the details of construction and arrangement of components set forth in the following description or illustrated in the drawings. The present disclosure is capable of other implementations and of being practiced or carried out in various ways.

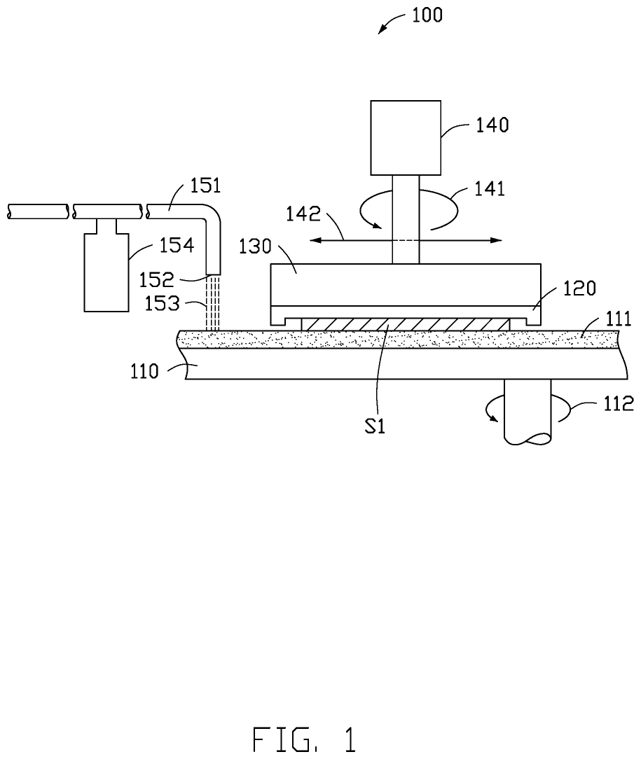

FIG. 1 illustrates a schematic diagram of a chemical-mechanical planarization (CMP) apparatus. The CMP apparatus 100 includes a carrier head 130 and a retaining ring 120. A semiconductor wafer S1 is held in the retaining ring 120. A soft pad (not shown in the figure) is positioned between the retaining ring 120 and the wafer S1, while the wafer S1 is held against the soft pad by a partial vacuum or with an adhesive. The carrier head 130 is provided to be continuously rotated by a drive motor 140, in the direction 141, and additionally may be reciprocated transversely in the directions 142. Accordingly, the combined rotational and transverse movements of the wafer S1 are intended to reduce the variability in the material removal rate across the surface of the wafer S1. The CMP apparatus 100 further includes a platen 110, which is rotated in the direction referenced at 112. A polishing pad 111 is mounted on the platen 110. As compared to the wafer S1, the platen 110 is provided with a relatively large surface area to accommodate the translational movement of the wafer S1 held by the retaining ring 120 along the surface of the polishing pad 111. A supply tube 151 is mounted above the platen 110 to deliver a stream of polishing slurry 153, which is dripped onto the surface of the polishing pad 111 from a nozzle 152 of the supply tube 151. The slurry 153 may be gravity fed from a tank or reservoir (not shown), or otherwise pumped through the supply tube 151. Alternatively, the slurry 153 may be supplied from below the platen 110 such that it flows upwardly through the underside of the polishing pad 111. In another embodiment, the slurry may be supplied in the retaining ring 120 by nozzles disposed in the retaining ring 120. If the particles in the slurry 153 forms agglomeration of undesirable large particles, the wafer surface would be scratched when the wafer S1 is being polished. Therefore, the slurry 153 needs to be filtered to remove the undesirable large particles. Usually, a filter assembly 154 is coupled to the supply tube 151 to separate agglomerated or oversized particles.

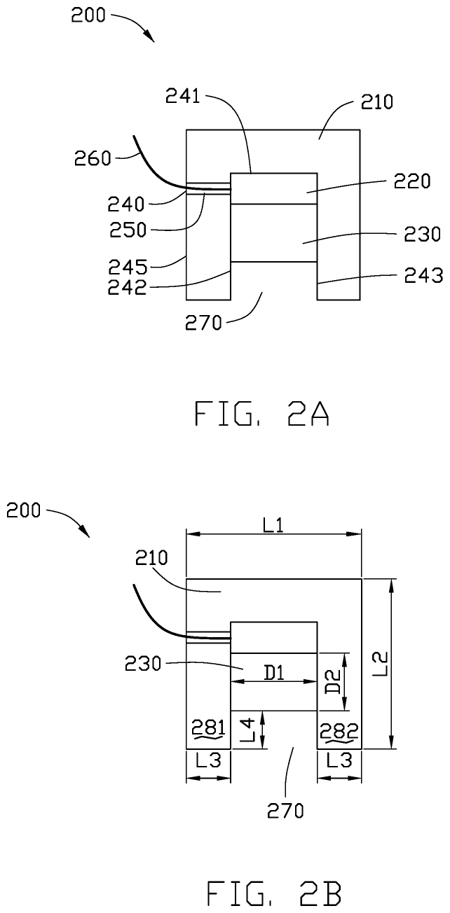

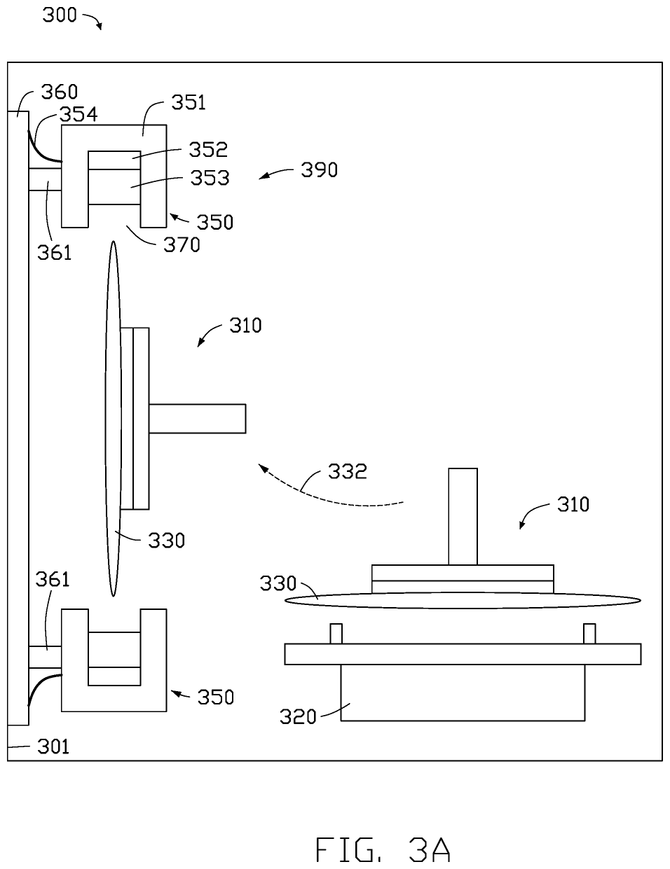

FIG. 2A illustrates a cross-sectional view of a wafer trimming module 200 in accordance with an implementation of the present disclosure. As shown in FIG. 2A, the wafer trimming module 200 includes a wafer trimming holder 210, a chemical liquid supply member 220, and a polishing pad 230. The wafer trimming holder 210 has an opening 270 for accommodating the chemical liquid supply member 220 and the polishing pad 230. The opening 270 includes a bottom 241, a first sidewall 242, and a second sidewall 243. The chemical liquid supply member 220 is attached to the bottom 241, between the first sidewall 242, and the second sidewall 243. The polishing pad 230 is coupled to the chemical liquid supply member 220; for example, the polishing pad 230 is attached to the chemical liquid supply member 220, between the first sidewall 242, and the second sidewall 243. In some examples, the polishing pad 230 is deformable or compressible.

In some embodiments, the wafer trimming holder 210 and the chemical liquid supply member 220 may be made of polytetrafluoroethylene (also known for the tradename Teflon®). The polishing pad 230 may be made of a material selected from the group consisting of polyurethane, polyvinyl acetate (PVA), polyester, and fiber. The hardness of the polishing pad 230 may fall within the range of 10 to 40 Shore D. The compressibility of the polishing pad 230 may fall within the range of 10 to 50%.

Still referring to FIG. 2A, the wafer trimming holder 210 has a side hole 250 for accommodating a chemical liquid supply tube 260. The side hole 250 extends from an inner surface of the first sidewall 242 to an outer surface 245 of the wafer trimming holder 210 so as to form a lateral opening 240. In some embodiments, the side hole 250 may extends from an inner surface of the second sidewall 243. The chemical liquid supply tube 260 may be connected to a chemical liquid supply source (not shown) at one end, and connected to the chemical liquid supply member 220 at the opposing end. For example, the chemical liquid supply tube 260 may be glued on, affixed to, or attached to the chemical liquid supply member 220.

The chemical liquid supply source (not shown) pumps a chemical liquid into the chemical liquid supply tube 260. The chemical liquid may be a slurry for chemical-mechanical planarization (CMP). Subsequently, the chemical liquid is received by the chemical liquid supply member 220 and transferred to the polishing pad 230. The chemical liquid supply member 220 may act as an intermediate buffer between the chemical liquid supply tube 260 and the polishing pad 230. Moreover, the polishing pad 230 may have pores so that the slurry may be soaked into the polishing pad 230. Porous material can be used as a material of the polishing pad 230. The density of the pores on the polishing pad 230 may fall within the range of 10 to 50 g/cm³, and the size of each of the pores may fall within the range of 30 to 60 μm.

FIG. 2B illustrates a cross-sectional view showing dimensions of the wafer trimming holder 210 in accordance with an implementation of the present disclosure. As shown in FIG. 2B, the length L1 of the wafer trimming holder 210 may fall within the range of 6 to 20 mm; the height L2 of the wafer trimming holder 210 may fall within the range of 6 to 20 mm; the width L3 of a first portion 281 of the wafer trimming holder 210 may fall within the range of 1 to 5 mm; the width L3 of a second portion 282 of the wafer trimming holder 210 may fall within the range of 1 to 5 mm; and the depth L4 from the surface of the polishing pad 230 to the top of the opening 270 may fall within the range of 1 to 5 mm. The width D1 and length D2 of the polishing pad 230 may fall within the range of 2 to 10 mm.

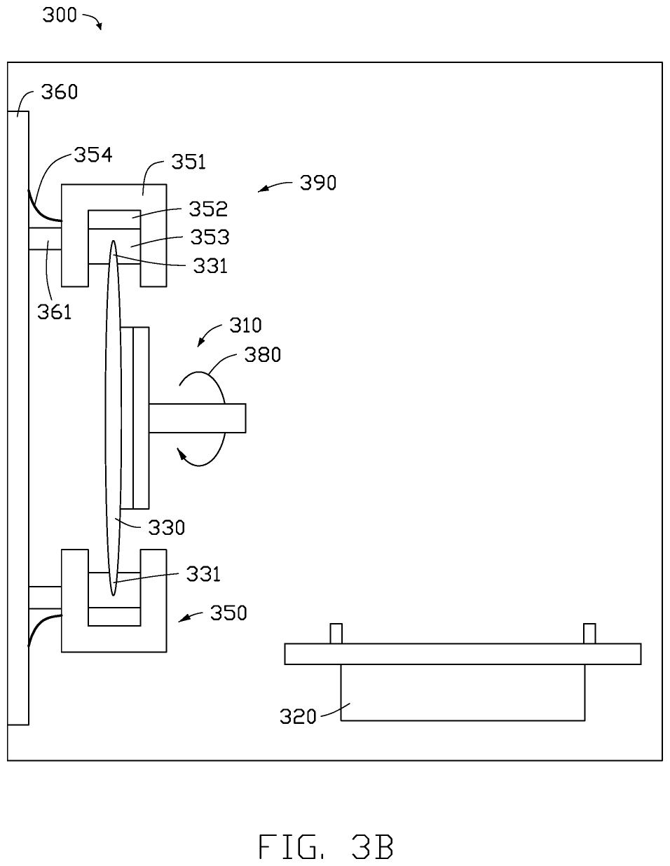

FIGS. 3A-3B illustrate side views of a chamber 300 having a vertical wafer trimming system 390 in accordance with an implementation of the present disclosure. As shown in FIG. 3A, the chamber or a clean station 300 includes a wafer handling arm 310, a wafer chuck 320, and the vertical wafer trimming system 390. The vertical wafer trimming system 390 may be fastened to a sidewall 301 of the chamber 300.

The vertical wafer trimming system 390 includes a control unit or a control base 360, a pair of wafer trimming modules 350, two rods 361, and two chemical liquid supply tubes 354. Each of the wafer trimming modules 350 includes a wafer trimming holder 351, a chemical liquid supply member 352, and a polishing pad 353. The rod 361 may be attached to the control unit 360 at one end, the wafer trimming module 350 is attached to the other end. The chemical liquid supply tube 354 connects a chemical liquid supply source (not shown) and the wafer trimming module 350 for supplying a chemical liquid to the polishing pad 353. The chemical liquid supply source may be placed within the control unit 360, or elsewhere near the chamber 300 and independently from the control unit 360.

In some examples, the rod 361 is fastened to a gliding rail (not shown) of the control unit 360. Accordingly, the pair of wafer trimming modules 350 may move along a rail (not shown) of the gliding rail.

In some embodiments, each of the pair of wafer trimming modules 350 has an opening 370. The openings 370 may be disposed opposite each other so that the pair of wafer trimming modules 350 may clamp the wafer during the trimming process. The quantity of the wafer trimming module 350 shown in FIG. 3A is exemplary, and is not limited to a pair. The vertical wafer trimming system 390 may have one or more wafer trimming modules. The quantity of the wafer trimming module may be odd or even numbered.

Still referring to FIG. 3A, the wafer handling arm 310 may lift a wafer 330, and move to a predetermined position for trimming as exemplified by a dashed arrow 332. The wafer 330 may be positioned vertically and in alignment with the pair of wafer trimming modules 350. Specifically, the wafer 330 is placed between the pair of wafer trimming modules 350 so that the wafer trimming module 350, the wafer 330, and the wafer trimming module 350 are vertically aligned.

As shown in FIG. 3B, a wafer trimming process is performed. Specifically, as the wafer 330 reaches the predetermined position, the pair of wafer trimming modules 350 move toward the wafer 330 to clamp the wafer 330 from wafer edges 331. In some examples, the movement of the pair of wafer trimming modules 350 is programmed. When the wafer edges 331 are pushed or pressed into the polishing pads 353 and reaches a predefined depth therein, the wafer handling arm 310 begins to rotate as exemplified by an arrow 380 so as to start the wafer trimming process. In some embodiments, the wafer handling arm 310 is static.

In one example, prior to an engagement of the wafer 330 by the trimming system, the polishing pad 353 absorbs the slurry used for polishing or scrubbing. A portion of the polishing pad 353 is compressed by the wafer edge 331. Both sides or the bevel area of the wafer edge 331 may be trimmed. When the wafer trimming process is completed, the pair of wafer trimming modules 350 return to the position prior to the engagement so as to release the wafer 330. In another example, the polishing pad 353 may absorb the slurry after the engagement of the wafer edge 331.

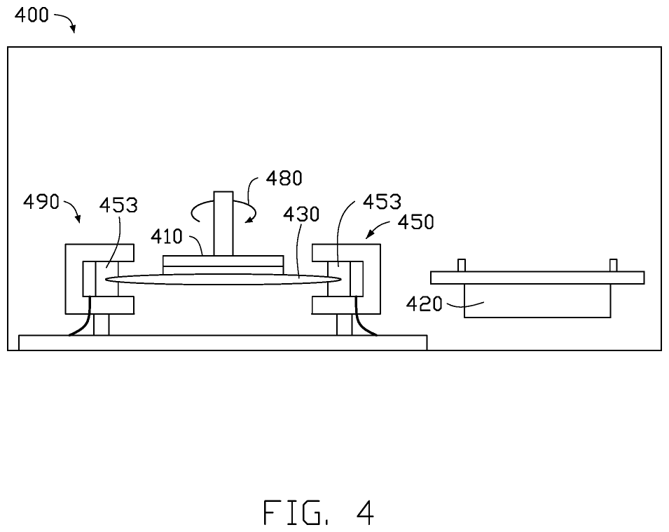

FIG. 4 illustrates a side view of a chamber 400 having a horizontal wafer trimming system 490 in accordance with an implementation of the present disclosure. The chamber 400 includes a wafer handling arm 410, a wafer chuck 420, a wafer 430, and the horizontal wafer trimming system 490. The operation procedure of the horizontal wafer trimming system 490 is similar to the vertical wafer trimming system 390 shown in FIGS. 3A-3B. The wafer 430 is transferred from the wafer chuck 420 to a predetermined position for edge trimming. The wafer 430 is disposed horizontally and in alignment with the wafer trimming modules 450. After the wafer is aligned with the wafer trimming modules 450, the wafer trimming modules 450 move toward the wafer 430 to clamp the wafer 430 from the wafer edge. When the wafer edge is pushed into polishing pads 453 and reaches a predefined depth therein, wafer handling arm 410 begins to rotate as exemplified by an arrow 480 so as to start the wafer trimming process.

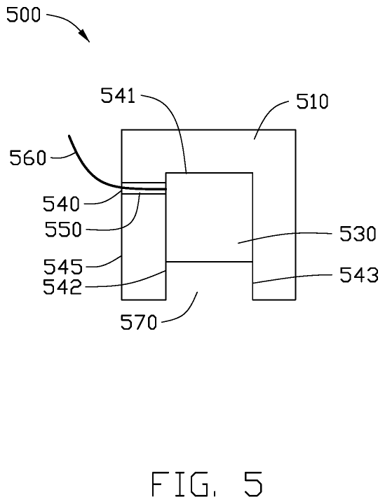

FIG. 5 illustrates a cross-sectional view of a wafer trimming module 500 in accordance with an implementation of the present disclosure. As shown in FIG. 5, the wafer trimming module 500 includes a wafer trimming holder 510 and a polishing pad 530. The wafer trimming holder 510 has an opening 570 for accommodating the polishing pad 530. The opening 570 includes a bottom 541, a first sidewall 542, and a second sidewall 543. The polishing pad 530 is attached to the bottom 541, the first sidewall 542, and the second sidewall 543. In some examples, the polishing pad 530 is deformable or compressible.

The wafer trimming holder 510 has a side hole 550 for accommodating a chemical liquid supply tube 560. The side hole 550 extends from an inner surface of the first sidewall 542 to an outer surface 545 of the wafer trimming holder 510 so as to form a lateral opening 540. In some embodiments, the side hole 550 may extends from an inner surface of the second sidewall 543. The chemical liquid supply tube 560 may be connected to a chemical liquid supply source (not shown) at one end, and be connected to the polishing pad 530 at the opposing end. For example, the chemical liquid supply tube 560 is glued on, affixed to, or attached to the polishing pad 530.

The various implementations of the present disclosure provide several benefits. In one aspect, both sides of the edge of the wafer can be easily trimmed by the wafer trimming system. In the other aspect, the wafer trimming system can be integrated with the chamber, vertically, horizontally, or along an inclined direction. The flexibility of the installation of the wafer trimming system improves space efficiency in the chamber.

Terminology used herein is for the purpose of describing particular implementations only and is not intended to be limiting of implementations of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to implementations of the present disclosure in the form disclosed. Many modifications and variations will be apparent to those of ordinary skill in the art without departing from the scope and spirit of implementations of the present disclosure. The implementation was chosen and described in order to best explain the principles of implementations of the present disclosure and the practical application, and to enable others of ordinary skill in the art to understand implementations of the present disclosure for various implementations with various modifications as are suited to the particular use contemplated.

Although specific implementations have been illustrated and described herein, those of ordinary skill in the art appreciate that any arrangement which is calculated to achieve the same purpose may be substituted for the specific implementations shown and that implementations of the present disclosure have other applications in other environments. This present disclosure is intended to cover any adaptations or variations of the present disclosure. The following claims are in no way intended to limit the scope of implementations of the present disclosure to the specific implementations described herein.

Various examples have been described. These and other examples are within the scope of the following claims.

What is claimed is:

1. A wafer trimming module comprising:
a holder comprising an opening; and
a polishing pad attached to a bottom and a sidewall of the opening,
wherein the polishing pad is compressible.

2. The wafer trimming module of claim 1, wherein the sidewall further comprises a through hole for accommodating a liquid supplying tube.

3. The wafer trimming module of claim 2, wherein the liquid supplying tube is attached to the polishing pad for supplying a liquid.

4. The wafer trimming module of claim 3, wherein the liquid is a slurry for chemical-mechanical planarization (CMP).

5. A wafer trimming module, the module comprising:
a holder comprising an opening;
a liquid supply member attached to a bottom and a sidewall of the opening; and
a polishing pad coupled to the liquid supply member,
wherein the polishing pad is compressible.

6. The wafer trimming module of claim 5, wherein the sidewall further comprises a through hole for accommodating a liquid supplying tube.

7. The wafer trimming module of claim 6, wherein the liquid supplying tube is attached to the liquid supply member for supplying a liquid.

8. The wafer trimming module of claim 7, wherein the liquid is a slurry for chemical-mechanical planarization (CMP).

9. The wafer trimming module of claim 8, wherein the polishing pad comprises a plurality of pores for allowing the slurry to be soaked into the polishing pad.

10. The wafer trimming module of claim 9, wherein a density of the plurality of pores falls within a range of 10 to 50 g/cm³.

11. The wafer trimming module of claim 9, wherein a size of the plurality of pores falls within a range of 30 to 60 μm.

12. The wafer trimming module of claim 5, wherein the holder is made of polytetrafluoroethylene.

13. The wafer trimming module of claim 5, wherein the polishing pad is made of a material selected from a group consisting of polyurethane, polyvinyl acetate (PVA), polyester, and fiber.

14. The wafer trimming module of claim 5, wherein a hardness of the polishing pad falls within a range of 10 to 40 Shore D.

15. The wafer trimming module of claim 5, wherein a compressibility of the polishing pad falls within a range of 10 to 50%.

16. A wafer trimming system comprising:
a control unit; and
at least one wafer trimming module attached to the control unit, the at least one wafer trimming module comprising:
a holder comprising an opening;
a liquid supply member configured to be attached to a bottom and a sidewall of the opening; and
a compressible polishing pad configured to be attached to the liquid supply member and the sidewall of the opening.

17. The wafer trimming system of claim 16, wherein the control unit is configured to be fastened to a sidewall or a bottom of a chamber of the wafer trimming system.

18. The wafer trimming system of claim 17, wherein the at least one wafer trimming module is configured to move toward a wafer for performing a trimming process to a wafer.

19. The wafer trimming system of claim 18, wherein an edge of the wafer is pressed into the compressible polishing pad for a predefined depth during the trimming process.

20. The wafer trimming system of claim 16, wherein the control unit further comprises a gliding rail for guiding a movement of the at least one wafer trimming module.
